(19) United States
(12) Patent Application Publication
(10) Pub. No.: US 2025/0113572 A1
(43) Pub. Date: Apr. 3, 2025

(54) METHOD OF FABRICATING A 2D CHANNEL TRANSISTOR BY EMPLOYING SELECTIVE METALLIZATION TO FORM A SOURCE OR DRAIN STRUCTURE

(71) Applicant: Intel Corporation, Santa Clara, CA (US)

(72) Inventors: Mahmut Sami Kavrik, Hillsboro, OR (US); Uygar E. Avci, Portland, OR (US); Kevi P. Obrien, Portland, OR (US); Chia-Ching Lin, Portland, OR (US); Carl H. Naylor, Portland, OR (US); Kirby Maxey, Hillsboro, OR (US); Andrey Vyatskikh, Hillsboro, OR (US); Scott B. Clendenning, Portland, OR (US); Matthew Metz, Portland, OR (US); Marko Radosavljevic, Portlan, OR (US)

(73) Assignee: Intel Corporation, Santa Clara, CA (US)

(21) Appl. No.: 18/375,060

(22) Filed: Sep. 29, 2023

(51) Int. Cl. H01L 29/18; H01L 21/8238; H01L 27/092; H01L 29/06; H01L 29/417; H01L 29/423; H01L 29/66; H01L 29/775; H01L 29/786

(52) U.S. Cl. CPC H10D 62/84; H10D 30/014; H10D 30/43; H10D 30/6729; H10D 30/6735; H10D 30/6757; H10D 62/121; H10D 84/0167; H10D 84/017; H10D 84/038; H10D 84/85

(57) ABSTRACT

Techniques and mechanisms for forming a gate dielectric structure and source or drain (S/D) structures on a monolayer channel structure of a transistor. In an embodiment, the channel structure comprises a two-dimensional (2D) layer of a transition metal dichalcogenide (TMD) material. During fabrication of the transistor structure, a layer of a dielectric material is deposited on the channel structure, wherein the dielectric material is suitable to provide a reaction, with a plasma, to produce a conductive material. While a first portion of the dielectric material is covered by a patterned structure, a second portion of the dielectric material is exposed to a plasma treatment to form a source or dielectric (S/D) electrode structure that adjoins the first portion. In another embodiment, the dielectric material is an oxide of a Group V-VI transition metal.

### BACKGROUND

### 1. Technical Field

This disclosure generally relates to the fabrication of integrated circuitry and more particularly, but not exclusively, to the formation of a transistor which comprises a transition metal dichalcogenide (TMD).

### 2. Background Art

Demand for integrated circuits (ICs) in portable electronic applications has motivated greater levels of semiconductor device integration. Many advanced semiconductor devices in development leverage non-silicon semiconductor materials. One class of those materials is the transition metal dichalcogenide (TMD or TMDC). Similar to graphene, TMDs display semiconductor properties as a unit cell of MX2, where M is a transition metal atom (e.g., Mo, W) and X is a chalcogen atom (S, Se, or Te). TMD materials have been of significant interest in highly-scaled integrated circuitry (IC), in part because of the thin active layers possible. TMD-channeled transistors therefore have excellent short channel properties. It has also been shown that many TMD materials have good electron and hole mobility, making them interesting for complementary short channel devices (e.g., Lg<20 nm).

Recent TMD-based transistor designs are facilitated by (for example, implemented with) one or more TMD structures each being implemented as a respective “2D material”—i.e., as a material layer, at least a substantial portion of which is not more than one molecule in thickness. However, implementation of 2D materials in field effect transistors (FETs) has proven to be a challenge, and have resulted in various complications such material defects which contribute to contact resistance. These defects, such as S or Se vacancies, tend to arise during 2D material growth, but can also occur during conventional CMOS transistor fabrication processing which deteriorates a 2D material. As successive generations of transistor designs continue to decrease in scale, there is expected to be an increasing premium placed on improvements to the fabrication of a 2D material and structures proximate thereto.

### BRIEF DESCRIPTION OF THE DRAWINGS

The various embodiments of the present invention are illustrated by way of example, and not by way of limitation, in the figures of the accompanying drawings and in which:

FIG. 1 is a flow diagram illustrating a method for fabricating structures of a transistor which comprises a TMD material layer according to an embodiment.

FIGS. 2A-2J are perspective view diagrams illustrating respective structures each during a corresponding stage of processing to fabricate a transistor according to an embodiment.

FIGS. 3A-3F are cross-sectional side view diagrams illustrating respective structures each during a corresponding stage of processing to provide a material layer stack according to an embodiment.

FIGS. 4A-4H are cross-sectional side view diagrams illustrating respective structures each during a corresponding stage of processing to fabricate a transistor using a material layer stack according to an embodiment.

FIG. 5 is a cross-sectional side view of an IC structure, in accordance with some embodiments.

FIG. 6 is a functional block diagram illustrating a system which comprises a packaged IC die that includes transistor structures according to one embodiment.

FIG. 7 is a functional block diagram which illustrates an electronic computing device in accordance with some embodiments.

### DETAILED DESCRIPTION

Embodiments discussed herein variously provide techniques and mechanisms for forming source or drain (S/D) structures of a transistor while mitigating a risk of damage to a channel structure of the transistor. To enable feature size scaling in silicon channels, transistor architectures such as nanowire and stacked nanowires have been adopted. Nanowire transistors provide benefits such as near ideal sub-threshold slopes, low leakage current and less degradation of mobility with gate voltage compared to other transistor architectures. As dimensions of various components of nanowire transistors (channel width and gate length) are decreased to increase device density, device metrics such as carrier mobility and subthreshold slope, parasitic capacitance, may be adversely impacted. Nanosheet transistors that include monocrystalline silicon channels, in particular, are prone to mobility and subthreshold slope degradation as channel widths approach 7 nm. Mobility in silicon nanosheets diminishes by over 60% as nanosheets are scaled below 7 nm to 3.5 nm, for example.

Nanosheets fashioned from two dimensional materials, such as transition metal dichalcogenide (TMD), offer several advantages over conventional silicon. A monolayer of a TMD material may be on the order of 0.7 nm, or inherently 2-dimensional (2D). TMD materials have a high Young's modulus and can be utilized to form 2-D nanosheet transistors. The use of such 2D channel structures is limited, for example, by the susceptibility of the TMD materials to defects during deposition and/or during subsequent fabrication processes. Additionally, or alternatively, lithographic mask, etch and/or other such processes tend to result in the formation of residual contaminants (such as interlayer carbon) between a 2D channel structure and a source or drain (S/D) contact metal

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed to provide any of a variety of electronic devices including a transistor comprising structures which are an artefact of a dielectric being subjected to plasma treatment.

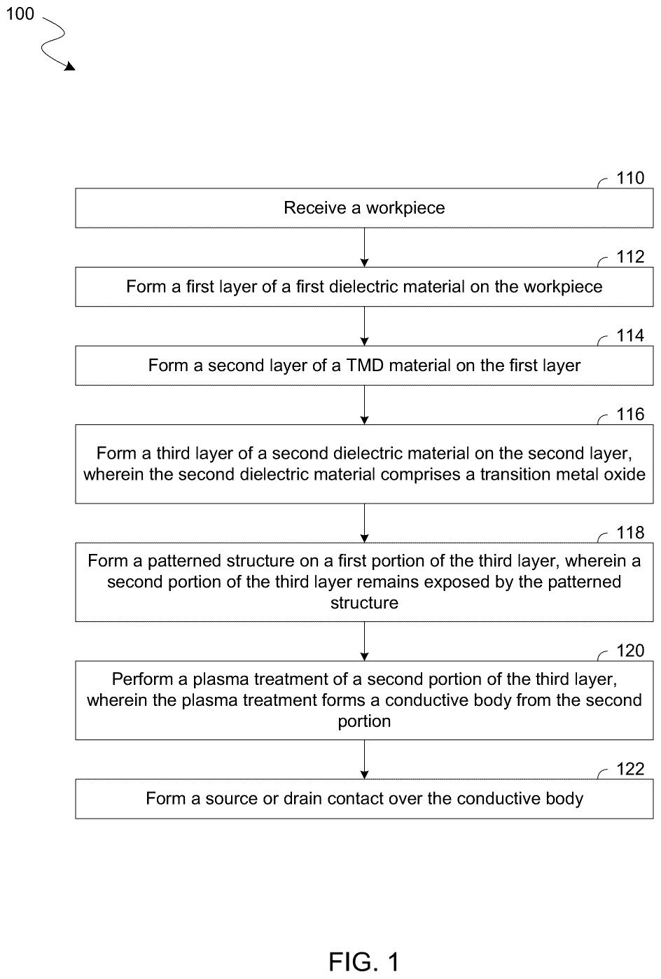

FIG. 1 shows a flow diagram illustrating features of a method to fabricate structures of a transistor which comprises a TMD material layer according to an embodiment. FIG. 1 shows a method 100 for fabricating structures of a transistor which comprises a TMD material layer according to an embodiment. The method 100 illustrates one example of an embodiment wherein one or more portions of a dielectric layer, which (for example) is formed on a channel structure, are exposed to a plasma to selectively metallize said one or more portions.

The term “partially metallized layer” refers herein to a structural layer which is formed as a result of plasma treatment of a dielectric layer. For example, plasma treatment is performed while a first portion of a dielectric layer is covered by a patterned resist structure, and while one or more other portions of the dielectric layer remain exposed by the patterned resist structure. Plasma treatment of the dielectric layer includes reacting a plasma with the exposed one or more other portions. The plasma scavenges oxygen from the dielectric material of the one or more other portions, where the one or more other portions are thus changed, by the reaction with the plasma, each into a respective conductive material.

In various embodiments, plasma treatment of such a dielectric layer mitigates a risk of damage to the channel structure, which in some embodiments comprises a 2D material (also variously referred to as a “monolayer”, a “monocrystalline structure”, or a “nanosheet”). Such damage could otherwise take place, for example, if the channel structure remained exposed during mask, pattern, etch, deposition and/or other processing to form one or more source or drain (S/D) electrode structures on the channel structure. Additionally or alternatively, such mask, pattern, etch, deposition and/or other processing could result in the formation of residual contaminants (such as interlayer carbon) between the channel structure and a S/D electrode metal.

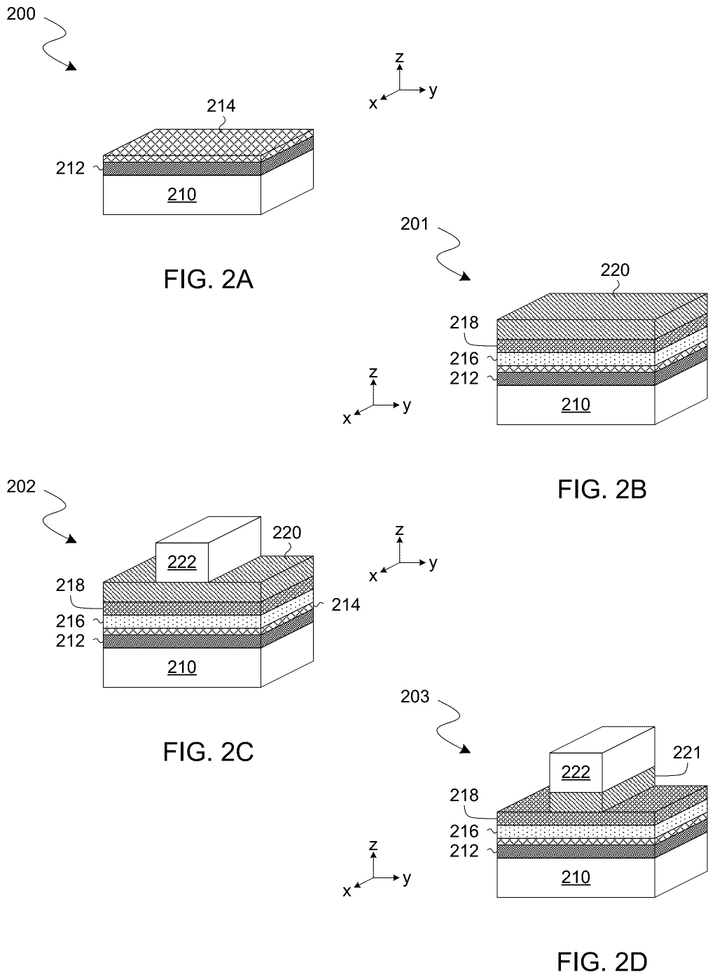

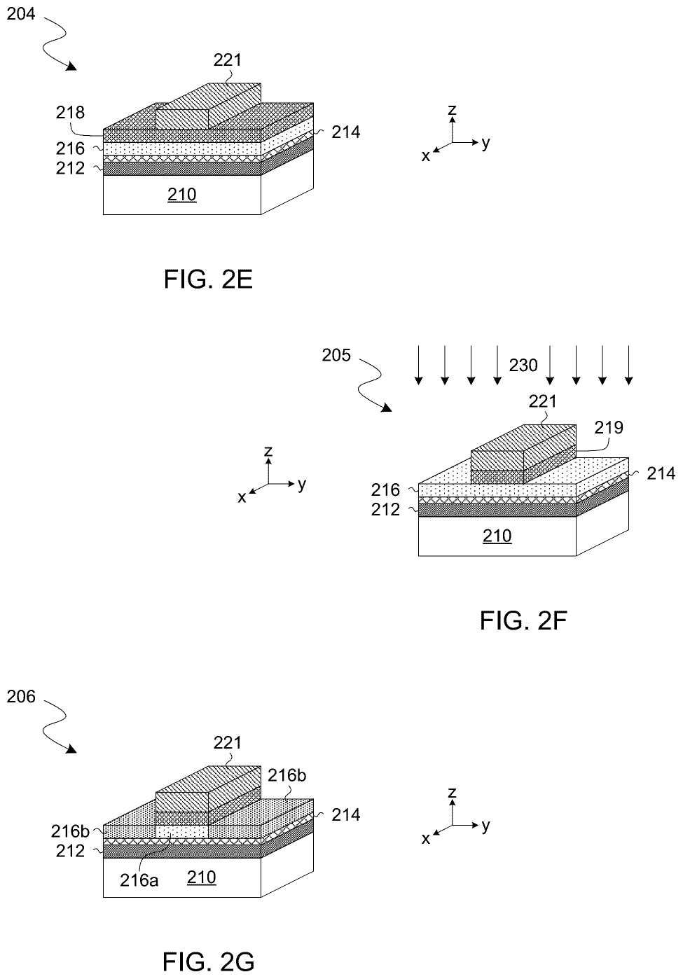

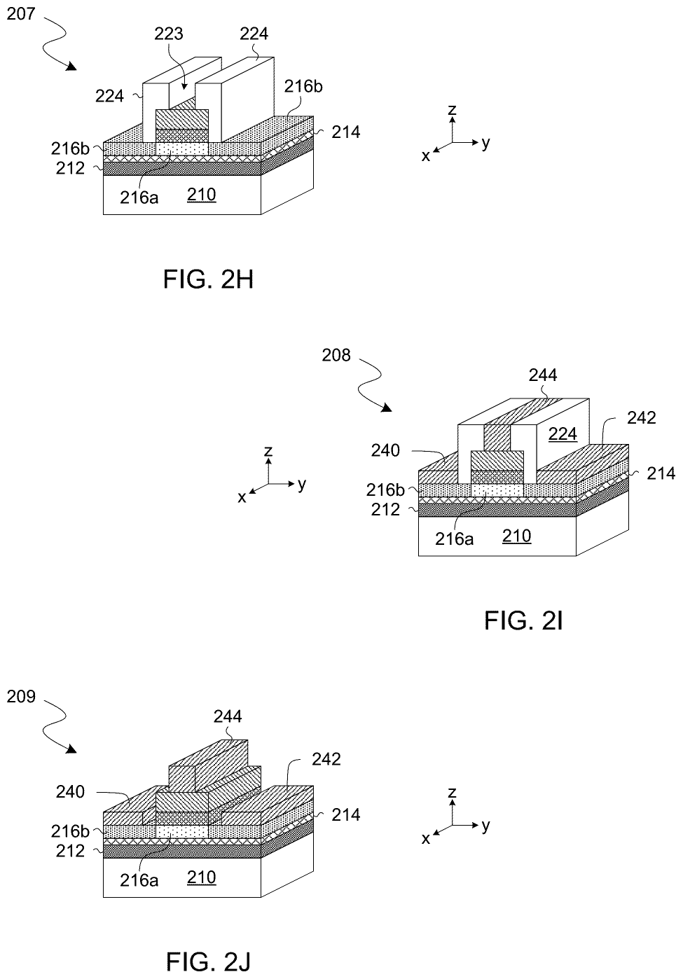

To illustrate certain features of various embodiments, method 100 is described herein with reference to structures which are variously formed during processing which is shown in FIGS. 2A-2J. However, it is to be appreciated that such description can be extended to include any of various additional or alternative structures, in various embodiments.

As shown in FIG. 1, method 100 comprises (at 110) receiving a workpiece which, for example, provides structural support for a deposition and/or other formation of various material layers thereon. The method 100 further comprises (at 112) forming on the workpiece a first layer of a first dielectric material which, for example, is to facilitate at least partial electrical insulation of one or more transistor structures which are subsequently to be formed thereon. By way of illustration and not limitation, a stoichiometry of the first dielectric material is substantially the same as that of hafnium oxide (HfO₂), hafnium zirconium oxide (HfZrO₂) or any of various other suitable dielectrics.

In an embodiment, the method 100 further comprises (at 114) forming a second layer of a TMD material on the first layer—e.g., wherein the TMD material (a 2D material, for example) is to provide a channel structure of a transistor. For example, referring now to FIGS. 2A-2J, the respective stages 200 through 209 shown illustrate processing to fabricate a transistor according to an embodiment. The stages 200 through 209 illustrate one example of an embodiment which forms a transistor structure that includes a partially metallized layer on a 2D material which is to function as a channel structure of the transistor structure. In various embodiments, processing such as that illustrated by stages 200 through 209 includes operations of method 100. Structures in FIGS. 2A-2J are shown with reference to an xyz Cartesian coordinate system. Unless otherwise indicated, “length” refers herein to a dimension along the x-axis of the coordinate system, wherein “width” and “height” refer to dimensions along the y-axis and along the z-axis (respectively) of the coordinate system.

As shown in FIG. 2A, a dielectric layer 212 is formed on a substrate 210 at stage 200, and a channel structure 214 is formed on dielectric layer 212. In an embodiment, the substrate 210 includes a suitable semiconductor material such as but not limited to, single crystal silicon, polycrystalline silicon and silicon on insulator (SOI) material, where a trilayer stack includes a layer of silicon oxide between two layers of monocrystalline silicon. In another embodiment, substrate 210 includes other semiconductor materials such as germanium, silicon germanium or a suitable group III-N or a group III-V compound.

Dielectric layer 212 includes any of various dielectric materials—e.g., including a high-k dielectric, for example—which are suitable to provide at least partial electrical insulation of a transistor structure which is to be formed by the processing shown. In some embodiments, a dielectric material of layer 212 includes one of: Hf, O, Si, Zr, Al, Sr, Ti, La, or Mo. For example, a stoichiometry of the dielectric material of layer 212 is substantially the same as that of one of: HfO₂, SiO₂, HfZrO₂, Al₂O₃, SrTiO₃, LaSrMoO₃, or their super lattices. In one such embodiment, layer 212 comprises a super lattice of any of two or more layers of material in an alternating fashion, where the layers of material include one or more of: HfO₂, SiO₂, HfZrO₂, Al₂O₃, SrTiO₃, or LaSrMoO₃. In some embodiments, the dielectric material of layer 212 includes one of the following elements: Hf, O, Si, Zr, Al, Sr, Ti, La, or Mo. In an embodiment, dielectric layer 212 is formed by operations which, for example, are adapted from any of various well-known techniques for depositing a dielectric material, such as chemical vapor deposition (“CVD”), physical vapor deposition (“PVD”), and atomic layer deposition (“ALD”).

In an embodiment, channel structure 214 comprises a transition metal dichalcogenide (TMD) or any of various other semiconductor materials which are suitable to be deposited or otherwise formed as a 2D material. A 2D semiconductor material is a type of natural semiconductor with thicknesses on the atomic scale. For example, channel structure 214 may have a thickness that is provided by a single atomic layer of the material (i.e., a monolayer of the 2D semiconductor material). In other embodiments, the channel structure 214 may comprise several layers of the 2D semiconductor material. In a particular embodiment, the channel structure 214 may comprise van der Waals 2D materials (2D materials for short). One class of 2D materials are TMDs. TMDs are a class of two-dimensional materials, which commonly have the chemical formula MX2, where M represents any of various transition metals, such as titanium, zirconium, hafnium, vanadium, niobium, tantalum, molybdenum, tungsten, technetium, rhenium, palladium, and platinum, and X represents a chalcogen, such as sulfur, selenium or tellurium. For example, TMD semiconductors may include, but are not limited to, MoS₂, WS₂, MoSe₂, WSe₂, MoTe₂, and WTe₂. It is to be appreciated that 2D materials are not limited to the TMDs. For example, 2D materials may also include indium selenide (InSe) and graphene.

In an embodiment, channel structure 214 is formed by operations which, for example, are adapted from any of various well-known techniques for forming one or more monolayers. By way of illustration and not limitation, channel structure 214 is grown by a seed-based technique in which an initial seed material is positioned in a desired location on the surface of dielectric layer 212, and a single-crystal 2D material, with no grain boundaries, is grown with the seed material as a template. In such embodiments, residue of the seed material (which may be different from the material grown on the seed) may remain in dielectric layer 212 (e.g., a residue of the seed material for channel structure 214 may remain in dielectric layer 212, etc.). In another example, channel structure 214 is grown by metal organic chemical vapor deposition (MOCVD). When a 2D layer is formed by MOCVD, the resulting material may not be single-crystal, but may have grains therein. In some embodiments, the grain sizes of channel structure 214 formed by MOCVD may be less than 5 microns (e.g., between 200 nanometers and 1 micron, between 200 nanometers and 5 microns, or between 1 micron and 5 microns). In other embodiments, other epitaxial techniques, such as molecular beam epitaxy (MBE) may be used. In still other embodiments, a 2D material is transferred from another substrate which is more suitable for growth of a TMD material.

Referring again to FIG. 1, method 100 further comprises (at 116) forming a third layer of a second dielectric material on the second layer, wherein the second dielectric material comprises an oxide of a transition metal (or “transition metal oxide” herein). In an embodiment, the second dielectric material is suitable to provide a reaction with a plasma, where such reaction (such as an oxygen scavenging reaction) is to produce a conductive material with the second dielectric material. In one such embodiment, the transition metal oxide comprises oxygen and a Group V-VI transition metal (i.e., a transition metal in one of the group V or the group VI).

For example, referring now to the stage 201 shown in FIG. 2B, a deposition process has formed, on channel structure 214, a layer 216 which is subsequently to be subjected to selective metallization. Layer 216 includes any of various dielectric materials which are suitable to serve as a reactant in a metallization process (e.g., a plasma treatment process) which produces a conductor from at least a portion of said dielectric material. In one such embodiment, layer 216 includes a transition metal oxide which comprises oxygen and a Group V-VI transition metal. For example, the Group V-VI transition metal is one of Nb, Ta, V, or Mo—e.g., wherein a stoichiometry of the dielectric material of layer 216 is substantially the same as that of one of Nb₂O₅, Ta₂O₅, V₂O₅ or MoO₃. In an embodiment, layer 216 is formed by CVD, PVD, ALD or any of various other suitable deposition processes which, for example, are adapted from conventional fabrication techniques.

Referring again to FIG. 1, method 100 further comprises (at 118) forming a patterned structure on a first portion of the third layer, wherein a second portion remains exposed by (i.e., is not covered by) the patterned structure. In an embodiment, the patterned structure formed at 118 includes one or more first patterned bodies each of a respective conductive material—e.g., wherein such one or more first patterned bodies are to provide gate electrode functionality of a transistor. Alternatively or in addition, the patterned structure includes one or more second patterned bodies each of a respective dielectric material—e.g., wherein such one or more second patterned bodies are to provide gate dielectric functionality of the transistor. Alternatively or in addition, the patterned structure includes a patterned mask material which is to be subsequently etched away or otherwise removed.

For example, referring again to stage 201, in various embodiments, a patterned structure is formed on layer 216 to facilitate a selective metallization processing of one or more portions of layer 216. In the example embodiment shown, the patterned structure is formed from one or both of a dielectric layer 218 and a conductive layer 220 which are variously formed on layer 216. Layer 218 comprises any of various dielectric materials which (for example) are suitable to function as a gate dielectric structure of a transistor—e.g., wherein conductive layer 220 comprises any of various conductive materials which are suitable to function as a gate electrode structure of the transistor. By way of illustration and not limitation, dielectric layer 218 includes one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate. In some embodiments, layer 218 has a thickness between 0.8 nm and 1.5 nm, for example. In various embodiments, dielectric layer 218 comprises multiple different constituent sub-layers (not shown) each of a different respective dielectric material. In still other embodiments, the structures at stage 201 omit layer 218—e.g., wherein conductive layer 220 (or some other structure to be subsequently patterned) is instead formed directly on layer 216.

Conductive layer 220 illustrates a body of any of various materials which are suitable to provide functionality of a gate electrode. For example, in some embodiments, such a body comprises a doped semiconductor and/or an elemental metal layer, a metal alloy layer, or a laminate structure of either or both. In some embodiments, conductive layer 220 comprises a metal nitride, such as TiN (e.g., having a work function in a range of 4.0-4.7 eV). For example, conductive layer 220 comprises one of titanium, aluminum, or nitrogen (for example)—e.g., wherein a stoichiometry of a conductive material of layer 220 is substantially the same as that of one of TiN or TiAlN. However, other alloy constituents may be additionally or alternatively employed in conductive layer 220—e.g., including, but not limited to, C, Ta, W, Pt, or Sn. In some embodiments, a conductor of layer 220 has a work function which is suitable to facilitate a desired channel threshold voltage (Vt) as a function of the composition of channel structure 214. In one such embodiment, conductive layer 220 advantageously has a work function below 5 eV. In an embodiment, the work function to provide with layer 220 depends on a 2D material type (e.g., n-type vs p-type). For example, for a p-type 2D material, it is typical to have a work function above 5 eV, whereas an n-type 2D material usually operates with a lower work function.

In the illustrative embodiment shown, the patterned structure formed on layer 216 is to additionally or alternatively comprise an etch resist structure which is formed, for example, using one or more operations that are adapted from conventional lithographic masking techniques. For example, at the stage 202 shown in FIG. 2C, a patterned resist PR 222 is formed on conductive layer 220. PR 222 comprises any of various suitable materials (e.g., a metal or dielectric material), and may be patterned using any suitable technique (e.g., a lithographic and etch technique). In one example embodiment, PR 222 includes silicon nitride, silicon oxynitride, silicon carbide or any of various other suitable mask materials—e.g., wherein a thickness of PR 222 is between 3 and 10 nanometers. PR 222 is located vertically (along the z-axis shown) over a portion of layer 216 which is to be protected from subsequent plasma treatment.

As shown in FIG. 2D, portions of conductive layer 220 have been selectively removed at stage 203—e.g., using any of various suitable wet etch techniques and/or dry etch techniques. In an embodiment, at least one other portion of conductive layer 220 has been protected by PR 222, and remains as a gate structure 221 which is under PR 222.

At the stage 204 shown in FIG. 2E, PR 222 has been removed from the top of gate structure 221, after which additional subtractive processing is performed to remove some or all of the portions of dielectric layer 218 which remain exposed by gate structure 221. At the stage 205 shown in FIG. 2F, such additional subtractive processing results in the formation of a gate dielectric structure 219 from the dielectric layer 218.

Referring again to FIG. 1, method 100 further comprises (at 120) performing a plasma treatment of a second portion of the third layer, wherein the plasma treatment forms a conductive body from the second portion. For example, after the plasma treatment at 120, the second portion comprises a conductive material. In an embodiment, the plasma treatment comprises exposing the second portion of the third layer to a plasma (e.g., a hydrogen plasma, a nitrogen plasma, an argon plasma, an ammonia plasma, or any of various combinations thereof), wherein the plasma reacts with the second portion to produce a conductive material with the second dielectric material of the second portion.

After the plasma treatment performed at 120, the second portion comprises the conductive material while the first portion comprises the second dielectric material. In an embodiment, the dielectric material of the first portion and the conductive material of the second portion have a first stoichiometry and a second stoichiometry (respectively) which variously comprise both oxygen and the same Group V-VI transition metal. For example, the second stoichiometry is substantially the same as that of a product of a reaction between a plasma and the second dielectric material. In one such embodiment, the first stoichiometry comprises a first mole ratio of oxygen to the Group V-VI transition metal, and the second stoichiometry comprises a second mole ratio of oxygen to the Group V-VI transition metal, wherein the second mole ratio is less than the first mole ratio.

In an illustrative scenario according to one embodiment, the first stoichiometry is substantially the same as that of one of niobium pentoxide (Nb₂O₅), tantalum pentoxide (Ta₂O₅), vanadium pentoxide (V₂O₅), or molybdenum trioxide (MoO₃). In one such embodiment, the second stoichiometry is substantially the same as that of one of niobium monoxide (NbO), vanadium (II) oxide, or molybdenum dioxide (MoO₂).

For example, referring again to the stage 205 shown in FIG. 2F, gate dielectric structure 219 covers one portion of layer 216, and is to protect said portion from a subsequent metallization treatment using a plasma 230 (such as a hydrogen plasma, a nitrogen plasma, an argon plasma, an ammonia plasma, or any of various combinations thereof) which acts as an oxygen scavenger. However, one or more other portions of layer 216 remain exposed by gate dielectric structure 219, and are subject to being at least partially metallized by an exposure to plasma 230 during the metallization treatment.

In some embodiments, portions of channel structure 214 are doped during the selective treatment of layer 216 with plasma 230. In other embodiments, such portions of channel structure 214 are doped by other processing (not shown) which, for example, is performed prior to deposition of layer 216 thereon. In various embodiments, doping of channel structure 214 includes operations adapted from conventional transistor fabrication techniques, which are not detailed herein, and are not limiting on some embodiments.

At the stage 206 shown in FIG. 2G, the treatment with plasma 230 has selectively metallized one or more portions of layer 216, to form conductive bodies 216b which are on opposite respective sides of (and, for example, which adjoin) a remaining dielectric body 216a. In various embodiments, an oxide of dielectric body 216a comprises oxygen and a Group V-VI transition metal, wherein one or each of conductive bodies 216b comprise a conductive material which includes oxygen and the Group V-VI transition metal. In one such embodiment, a stoichiometry of the transition metal oxide comprises a first mole ratio of oxygen to the Group V-VI transition metal. By contrast, a stoichiometry of the conductive material comprises a second mole ratio of oxygen to the Group V-VI transition metal, wherein the second mole ratio is less than the first mole ratio.

Referring again to FIG. 1, method 100 further comprises (at 122) forming a S/D contact over the conductive body. In various embodiments, the second portion is metallized by the plasma treatment to provide a first S/D electrode structure of a transistor structure, wherein the S/D contact is formed at 122 over the first S/D electrode structure. In one such embodiment, method 100 further comprises performing a plasma treatment of a third portion of the third layer, wherein the third portion is also exposed by the patterned structure which is formed at 118. For example, the first portion is between the second portion and the third portion—wherein the plasma treatment further reacts the plasma with the third portion to convert the second dielectric material of the third portion to a conductive material.

In one such embodiment, the plasma treatment performed at 120 results in the formation of a first conductive body and a second conductive body from the second portion and the third portion (respectively). For example, after the plasma treatment the first portion of the second dielectric material is between (and, for example, adjoins) the first and second conductive bodies—e.g., wherein the first portion is to provide a gate dielectric structure of the transistor structure, and wherein the first and second conductive bodies are each to provide a different respective S/D electrode structure of the transistor structure. In one such embodiment, the forming at 122 comprises metallization processing which (for example) forms a first S/D contact structure over the first conductive body, forms a second S/D contact structure over the second conductive body, and/or forms a gate contact structure over the first portion.

For example, referring now to FIG. 2H, at stage 207, another patterned resist PR 224 is formed along portions of gate structure 221 and, in some embodiments, on portions of conductive bodies 216b. For example, PR 224 extends along opposite sidewalls of gate structure 221—e.g., wherein at least some of conductive bodies 216b remain exposed by PR 224. In one such embodiment, PR 224 has formed therein an opening 223 which (for example) at least partially exposes a top surface of gate structure 221.

At the stage 208 shown in FIG. 2I, metal deposition processing forms S/D contacts 240, 242 each on a respective one of conductive bodies 216b, and further forms a gate contact 244 on gate structure 221. By way of illustration and not limitation, S/D contacts 240, 242 and gate contact 244 each comprise a respective metal which, for example, includes one of gold, copper, nickel, tungsten, molybdenum, titanium (e.g., as pure titanium and/or in the form of titanium nitride), and/or cobalt. After metal deposition to form S/D contacts 240, 242 and gate contact 244, PR 224 is removed—as illustrated by the stage 209 shown in FIG. 2J—to facilitate additional fabrication processing.

In various embodiments, method 200 comprises repeated instances—i.e., more than the one instance shown in FIG. 1—each of the sequential formation of a semiconductor (e.g., TMD) layer which is to provide a respective channel structure, and a dielectric layer which is to facilitate a subsequently formation of a respective partially metallized layer. By way of illustration and not limitation, method 200 further comprises forming a fourth layer of a third dielectric material (e.g., the first dielectric material) over the first portion (and, in some embodiments, over a gate electrode structure which is formed on the first portion. In one such embodiment, method 200 further comprises forming a fifth layer of the TMD material (or another suitable semiconductor material) on the fourth layer—e.g., wherein the fifth layer is a monolayer.

Furthermore, method 200 comprises forming a sixth layer of a fourth dielectric material (for example, the second dielectric material) on the fifth layer—e.g., wherein the fourth dielectric material comprises a transition metal oxide which accommodates metallization via a plasma treatment. In one such embodiment, method 200 further comprises forming a second patterned structure on a portion of a top side of the sixth layer—e.g., wherein one or more other portions of the top side of the sixth layer remain exposed by the second patterned structure. In an embodiment, the plasma treatment performed at 120 (or another such plasma treatment) further reacts a plasma with the one or more exposed portions of the sixth layer. The one or more exposed portions of the sixth layer react with the plasma each to form a respective conductive body—e.g., wherein the one covered portion of the sixth layer is between two such conductive bodies. In one such embodiment, the one or more conductive bodies formed by plasma treatment of the sixth layer are each to provide a different respective S/D electrode structure of the transistor structure (or of a different transistor structure)—e.g., wherein the covered portion of the sixth layer is to provide a gate dielectric structure of said transistor structure.

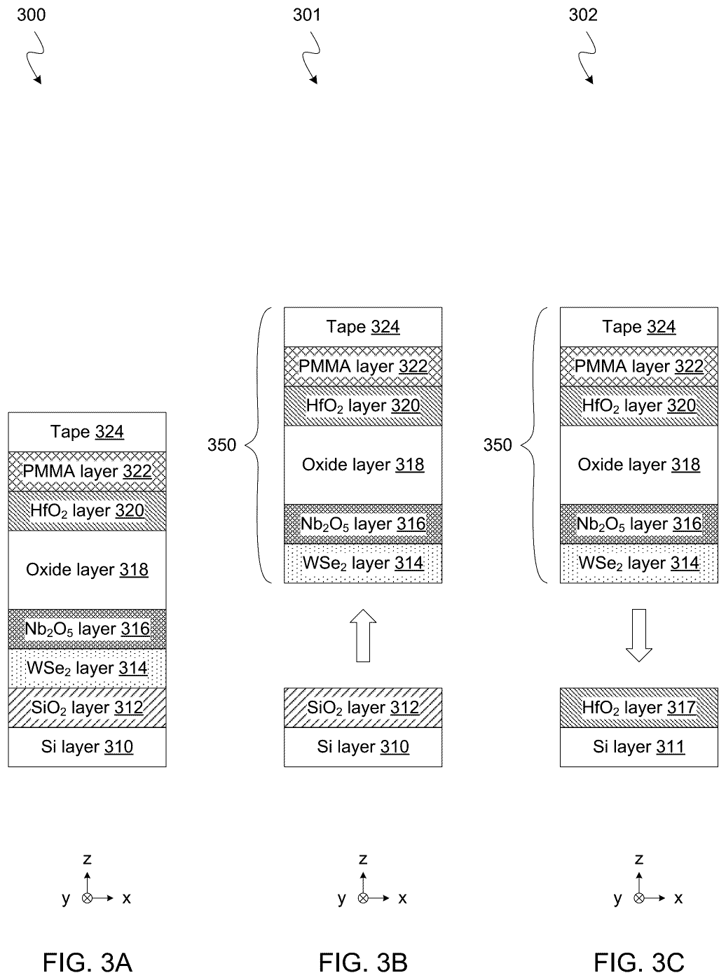

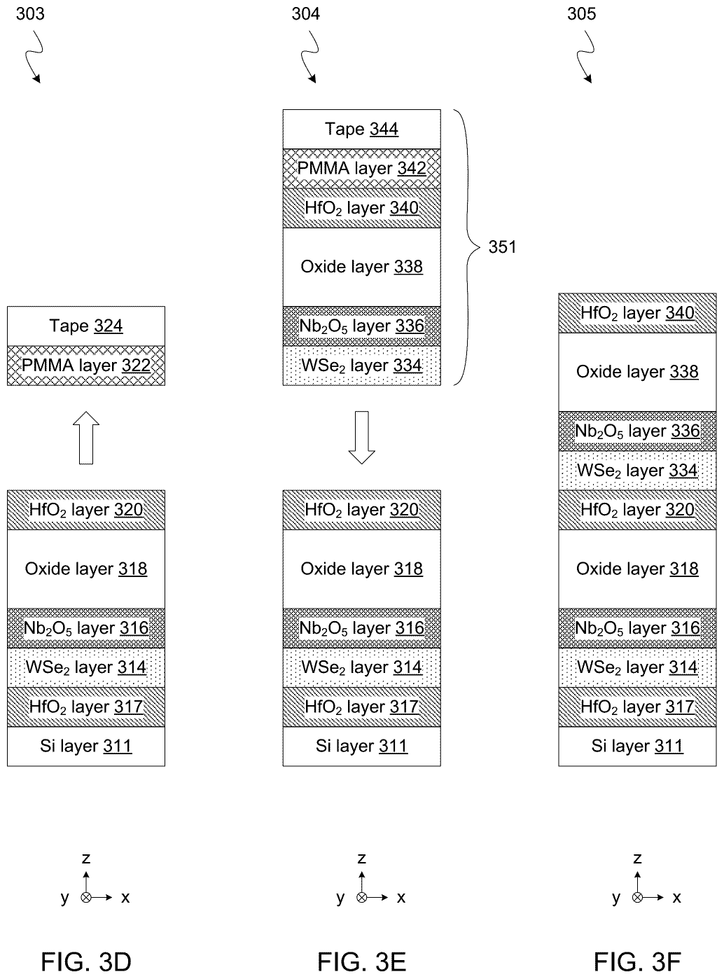

FIGS. 3A-3F show various stages 300 through 305 of processing to provide a material layer stack for fabricating transistor structures according to an embodiment. Structures in FIGS. 3A-3F are shown with reference to an xyz Cartesian coordinate system. In various embodiments, processing such as that illustrated by stages 300 through 305 provides a transistor structures which have features of the structures shown at stage 209—e.g., wherein said processing includes operations of method 100.

The stages 300 through 305 illustrate one example of an embodiment which forms multiple layers which are arranged in a vertical (z-axis) stack configuration. For example, the multi-layer stack comprises a plurality of TMD layers which are each to provide a different respective channel structure. Furthermore, the multi-layer stack comprises a plurality of dielectric layers which are each formed on (and, for example, which each adjoin) a different respective one of the TMD layers. The plurality of dielectric layers each comprise a respective dielectric material which is reactive to a plasma—e.g., where such a plasma reaction results in a respective conductive material being produced from the dielectric material in question. In an embodiment, the multi-layer stack is subsequently to be subjected to additional processing—e.g., comprising patterning and a plasma treatment process—to form some or all of a multi-channel (or other) transistor structure.

At the stage 300 shown in FIG. 3A, various deposition processes have been performed to generate a vertically (z-axis) stacked arrangement of material layers comprising, for example, a silicon (Si) layer 310, a silicon dioxide (SiO₂) layer 312, a tungsten diselenide (WSe₂) layer 314, a niobium pentoxide (Nb₂O₅) layer 316, an oxide layer 318, and a hafnium dioxide (HfO₂) layer 320. The layers 310, 312 illustrate any of various suitable combination of one or more support structures which facilitate a successive deposition of the other layers thereon. The WSe₂ layer 314 illustrates one example of a TMD (or other semiconductor material) which is suitable to provide at least one channel structure—e.g., wherein the material accommodates deposition or other formation as a 2D material. The Nb₂O₅ layer 316 illustrates one example of a dielectric—e.g., including an oxide of a Group V-VI transition metal-which is suitable for use in a plasma treatment process to selectively produce one or more conductive structures. The HfO₂ layer 320 illustrates one example of a high-k dielectric material which provides at least partial electrical insulation between a channel structure and one or more other circuit structures. In an embodiment, WSe₂ layer 314, Nb₂O₅ layer 316, and HfO₂ layer 320 variously provide functionality similar to that of channel structure 214, layer 216, and dielectric layer 212 (respectively).

Oxide layer 318 illustrates any of various oxide (or other) materials—such as silicon oxide, for example—which are suitable to be selectively etched by a given etch scheme which, in some embodiments, etches layer 318 at a much higher rate than some or all of Nb₂O₅, WSe₂, or HfO₂. In one such embodiment, portions of oxide layer 318 are to subsequently provide a patterned structure which facilitates a selective plasma treatment of Nb₂O₅ layer 316.

In some embodiments, a given material layer shown at stage 300 is formed using CVD, PVD, ALD or any of various other suitable deposition processes which, for example, are adapted from conventional fabrication techniques. In some embodiments, a given one or more material layer shown at stage 300 are deposited, transferred or otherwise provided using a mechanical support layer, e.g., by depositing (e.g., by spin-coating) a protective polymer layer, e.g., poly(methyl methacrylate) (PMMA), on top of a grown 2D material (e.g., TMD, or graphene). In one such embodiment, an additional, possibly much sturdier and thicker, mechanical support layer (e.g., transfer tape) is provided on top of the protective polymer layer, which is directly in contact with a given one or more layers, such as a grown 2D material layer, that are to be added to a material stack, moved to a target support structure, or the like. Together, the polymer layer with an additional mechanical support layer, such as a transfer tape, serve as a protective and mechanical support layer during the transfer of one or more 2D (or other) material layers.

In the example embodiment shown, multiple material layers shown at stage 300 have formed thereon a PMMA layer 322 and a transfer tape 324, which provide support for a transfer of said layers from the support structure provided with layers 310, 312. For example, at the stage 301 shown in FIG. 3B, an assembly 350 is formed by separating WSe₂ layer 314 from SiO₂ layer 312. With the support of PMMA layer 322 and tape 324, assembly 350 is transferred for adhesion (or other bonding) to another HfO₂ layer 317 which is deposited on a Si layer 311 (as illustrated by the stage 302 shown in FIG. 3C). In one such embodiment, Si layer 311 is Si layer 310—e.g., wherein HfO₂ layer 317 is deposited or otherwise formed thereon after an etching, planarization or other removal of SiO₂ layer 312.

At the stage 303 shown in FIG. 3D, assembly 350 is coupled via HfO₂ layer 317 to Si layer 311, after which PMMA layer 322 and tape 324 are removed from HfO₂ layer 320. Subsequently, as shown in FIG. 3E, another assembly 351 is adhered or otherwise bonded (at stage 304) to the remaining layers of assembly 350 via HfO₂ layer 320. In an embodiment, fabrication of assembly 351 is similar to that of assembly 350—e.g., wherein assembly 351 similarly comprises a WSe₂ layer 334, a Nb₂O₅ layer 336, an oxide layer 338, a HfO₂ layer 340, a PMMA layer 342, and a transfer tape 344. In one such embodiment, WSe₂ layer 334, Nb₂O₅ layer 336, and HfO₂ layer 340 variously provide functionality similar to that of channel structure 214, layer 216, and dielectric layer 212 (respectively)—e.g., wherein portions of oxide layer 338 are to subsequently provide a patterned structure which facilitates a selective plasma treatment of Nb₂O₅ layer 336. At the stage 305 shown in FIG. 3F, PMMA layer 342 and tape 344 are removed from HfO₂ layer 340—e.g., where, in some embodiments, such removal is to accommodate one or more additional layers being formed on HfO₂ layer 340.

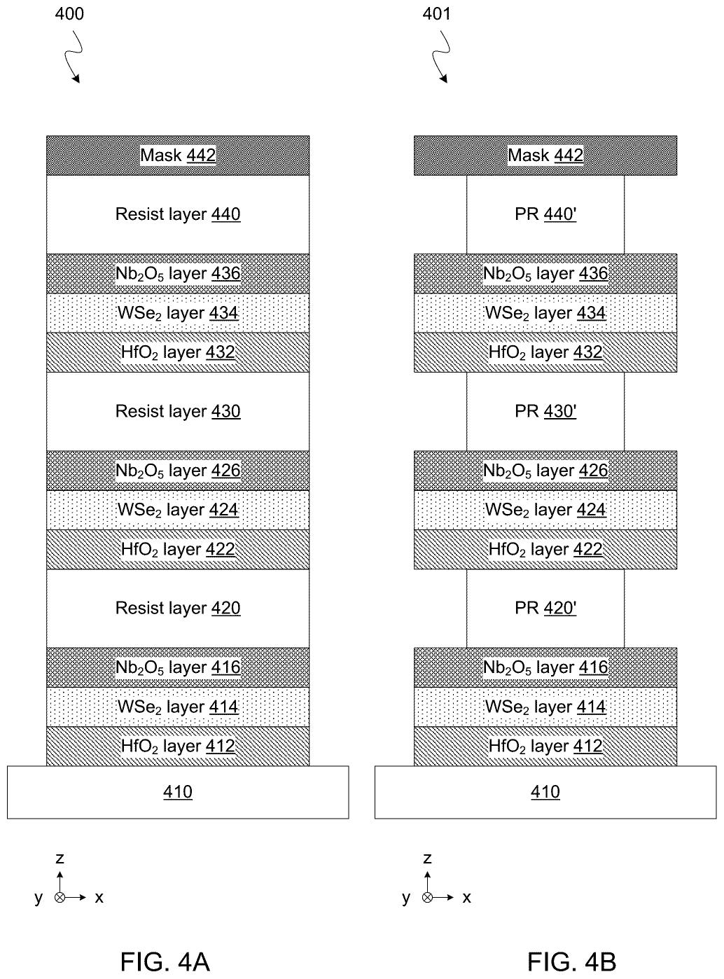

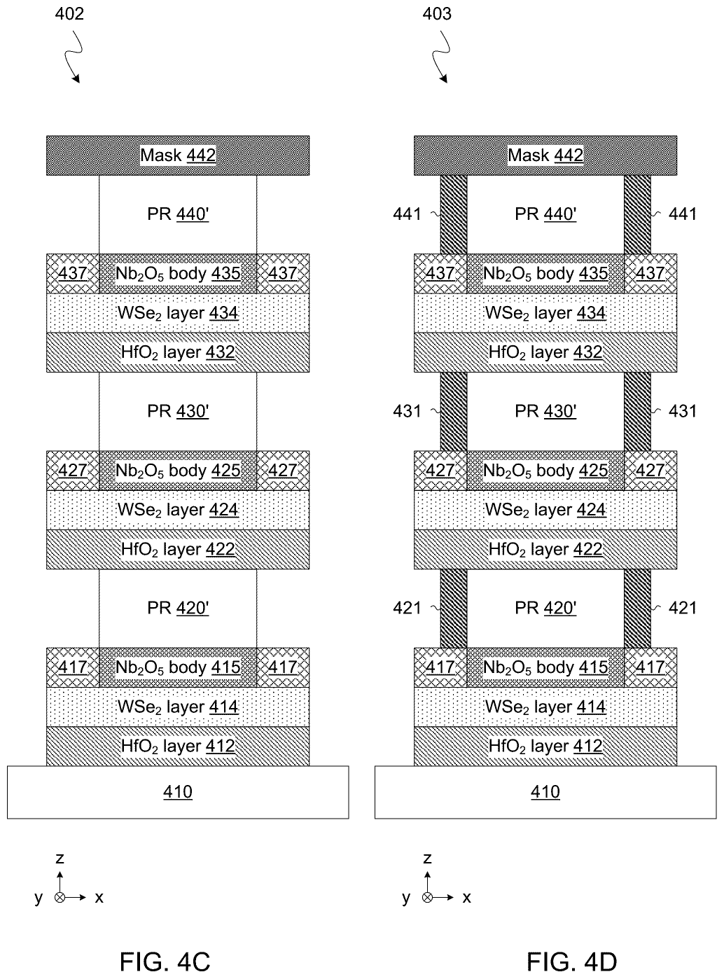

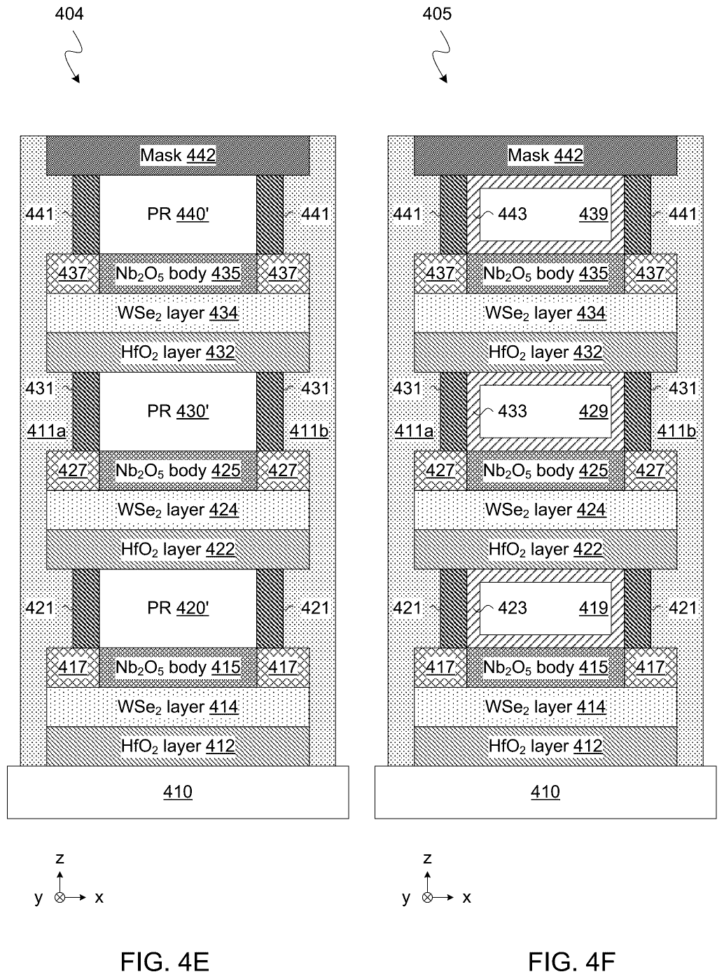

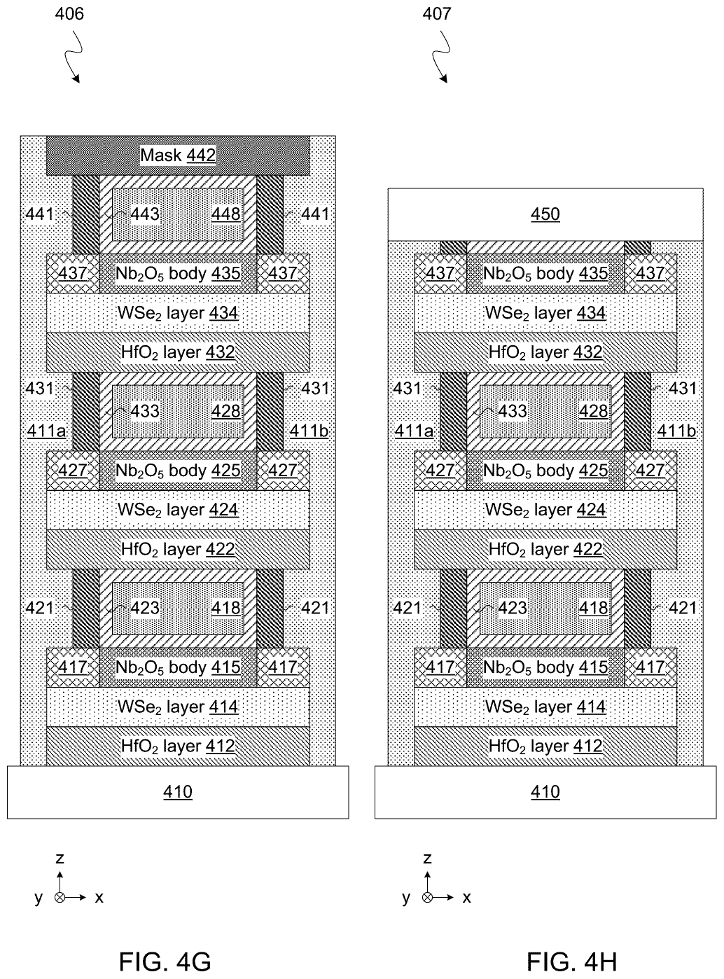

FIGS. 4A-4H show various stages 400 through 407 of structures each during a respective one of multiple stages 400 through 407 of processing to fabricate a transistor using a material layer stack according to an embodiment. Structures in FIGS. 4A-4H are shown with reference to an xyz Cartesian coordinate system. In various embodiments, processing such as that illustrated by stages 400 through 407 uses a stacked structure such as that shown in stage 305—e.g., wherein said processing includes operations of method 100.

The stages 400 through 407 illustrate one example of an embodiment which performs a selective plasma treatment of multiple dielectric layers which each adjoin a respective channel structure in a multi-layer stack. The selective plasma treatment comprises exposing portions of a given one such dielectric layer to a plasma, which acts as an oxygen scavenger that converts portions of the dielectric material each to a respective conductive body. For each of the multiple dielectric layers, a given conductive body formed from plasma treatment of the layer is to act as a S/D electrode structure of a corresponding transistor.

At the stage 400 shown in FIG. 4A, a multi-layer stack, formed on a substrate 410 (e.g., a silicon substrate, for example), comprises a HfO₂ layer 412, a WSe₂ layer 414, a Nb₂O₅ layer 416, a resist layer 420, and a HfO₂ layer 422, a WSe₂ layer 424, a Nb₂O₅ layer 426, a resist layer 430, a HfO₂ layer 432, a WSe₂ layer 434, a Nb₂O₅ layer 436, and a resist layer 440. By way of illustration and not limitation, HfO₂ layers 412, 422, 432 variously provide functionality such as that of HfO₂ layers 317, 320, 340—e.g., wherein WSe₂ layers 414, 424, 434 provide functionality such as that of WSe₂ layers 314, 334. In one such embodiment, Nb₂O₅ layers 416, 426, 436 variously provide functionality such as that of Nb₂O₅ layers 316, 336—e.g., wherein resist layers 420, 430, 440 provide functionality such as that of oxide layers 318, 338. In an embodiment, an etch resistant mask 442 is formed on resist layer 440 to provide additional protection during subsequent etching and/or other subtractive processing to selectively expose respective top side surfaces of Nb₂O₅ layers 416, 426, 436.

For example, referring now to FIG. 4B, a wet etch, or any of various other suitable subtractive processes, removes portions of resist layer 420 to form a patterned resist (PR) 420′ at stage 401. Similarly, such etching removes portions of resist layer 430 to form a PR 430′, and further removes portions of resist layer 440 to form a PR 440′. The PR 420′ covers a respective first portion of Nb₂O₅ layer 416, but leaves exposed respective second portions of Nb₂O₅ layer 416 (wherein the respective first portion is between the respective second portions). Similarly, PR 430′ only partially covers Nb₂O₅ layer 426, wherein PR 440′ only partially covers Nb₂O₅ layer 436.

At the stage 402 shown in FIG. 4C, a plasma treatment process has resulted in a partial metallization of each of Nb₂O₅ layers 416, 426, 436. For example, the plasma treatment results in an oxygen scavenging of exposed portions of Nb₂O₅ layer 416, where such exposed portions react with the plasma to produce conductive bodies 417 on opposite respective sides of a remaining (unexposed) Nb₂O₅ body 415. Furthermore, the plasma treatment includes reacting exposed portions of Nb₂O₅ layer 426 with the plasma to produce conductive bodies 427 on opposite respective sides of a remaining (unexposed) Nb₂O₅ body 425. Further still, the plasma treatment includes reacting exposed portions of Nb₂O₅ layer 436 with the plasma to produce conductive bodies 437 on opposite respective sides of a remaining (unexposed) Nb₂O₅ body 435.

At the stage 403 shown in FIG. 4D, spacer structures 421 are formed on opposite respective sides of PR 420′, wherein spacer structures 431 are similarly formed on opposite respective sides of PR 430′, and spacer structures 441 are formed on opposite respective sides of PR 440′. In an embodiment, some or all of PRs 420′, 430′, 440′ are subsequently to be replaced with gate electrode structures, wherein the spacer structures 421, 431, 441 are to variously provide insulation for such gate structures. In an embodiment, spacer structures 421, 431, 441 include any of various suitable materials such as silicon nitride, silicon oxide, silicon carbide, silicon nitride doped with carbon, and silicon oxynitride. In another embodiment, spacer structures 421, 431, 441 are formed prior to the plasma treatment which produces conductive bodies 417, 427, 437.

Referring now to FIG. 4E, at stage 404, metal deposition processing has formed a first S/D contact structure 411a which extends along one side of the multi-layer stack—e.g., wherein the S/D contact structure 411a adjoins respective first ones of conductive bodies 417, 427, 437. In one such embodiment, the metal deposition processing further forms a second S/D contact structure 411b which extends along an opposite side of the multi-layer stack—e.g., wherein the S/D contact structure 411b adjoins respective second ones of conductive bodies 417, 427,437.

In an embodiment, PRs 420′, 430′, 440′ variously extend along a horizontal (y-axis) direction each to a respective region which is available to be exposed to a wet etchant, for example. In one such embodiment, respective portions of PRs 420′, 430′, 440′ remain exposed by spacer structures 421, 431, 441—and by S/D contact structures 411a, 411b—to enable an etching process which removes some or all of PRs 420′, 430′, 440′.

For example, at the stage 405 shown in FIG. 4F, an etch process has resulted in a removal of the resist material of PM 420′ from the region 419 between spacer structures 421. Furthermore, the etch process removes the resist material of PM 430′ from a region 429 between spacer structures 431—e.g., wherein the resist material of PM 440′ is similarly removed from a region 439 between spacer structures 441. After said etch process, an ALD (or other suitable deposition process) is performed to form a dielectric liner structure 423 along a periphery of region 419. Similarly, such deposition processing forms a dielectric liner structure 433 along a periphery of region 429, as well as another dielectric liner structure 443 along a periphery of region 439.

In one example embodiment, after fabrication of the transistor is completed, gate electrode structure 418 is to provide a voltage which helps control a conduction of current between conductive bodies 417 via a channel structure which is provided with WSe₂ layer 414. Similarly, gate electrode structure 428 is to provide a voltage for a conduction of current between conductive bodies 427 via WSe₂ layer 424—e.g., wherein gate electrode structure 438 is to provide a voltage for a conduction of current between conductive bodies 437 via WSe₂ layer 434.

In some embodiments, a total number of nanoribbons (or other such channel structures) of a transistor is less than a total number of gate structures for controlling current conduction with said nanoribbons. By way of illustration and not limitation, as illustrated by the stage 407 shown in FIG. 4H, etching, planarization and/or other subtractive processing is performed to provide (e.g., under a layer 450 of silicon oxide or other suitable dielectric) a transistor which comprises two gate electrode structures 418, 428 to operate the three channel structures of WSe₂ layers 414, 424, 434. However, in other embodiments, the transistor includes a three channel, three gate design (for example) such as that shown in stage 406.

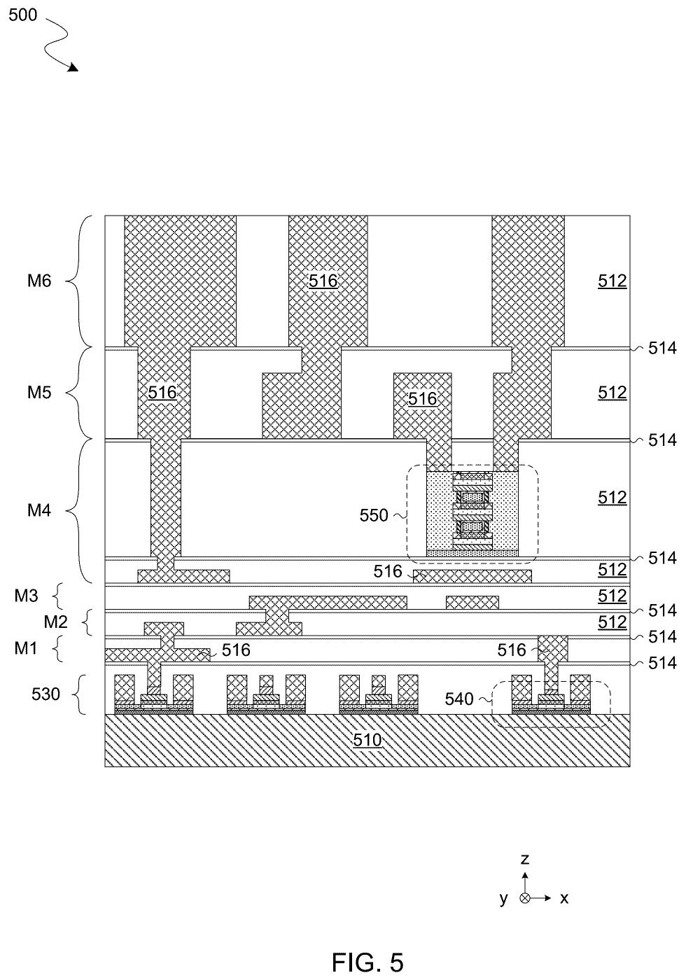

FIG. 5 illustrates a cross-sectional side view of an integrated circuit (IC) device 500 which comprises one or more transistors in accordance with some embodiments. IC device 500 illustrates a portion of a monolithic IC that includes front end of line (FEOL) circuit structures that are over and/or on a monocrystalline substrate 510. IC device 500 further includes back end of line (BEOL) circuit structures that are over and/or on the FEOL circuit structures. In an illustrative scenario according to one embodiment, the FEOL circuit structures comprise a transistor structure 540 which (for example) includes some or all of the features of the transistor shown in FIG. 2J. Alternatively or in addition, the FEOL circuit structures (or, in some embodiments, the BEOL circuit structures) comprise a transistor structure 550 which (for example) includes some or all of the features of the transistor shown in one of FIGS. 4G, 4H.

In the illustrated example, FEOL circuit structures include a plurality of field effect transistors (FETs) 530, one or more of which-such as the illustrative transistor structure 540 shown—each employs a respective TMD layer structure for at least a respective channel region of the transistor. Although some embodiments are not limited in this regard, the FEOL circuit structures further include any of various other types of transistors (e.g., bipolar junction transistor, etc.), and/or other active devices employing one or more semiconductor materials (e.g., diodes, lasers, etc.).

In the example embodiment shown, a channel structure of transistor structure 540 comprises a TMD layer which, for example, is a 2D material structure. Two S/D structures of transistor structure 540 are formed on the channel structure, as is a gate dielectric structure of the transistor structure 540. For example, the gate dielectric structure is between, and adjoins each of, the two S/D structures of transistor structure 540, wherein the gate dielectric layer and the two S/D structures are different respective portions of the same partially metallized layer. In one such embodiment, the gate dielectric structure comprises an oxide of a Group V-VI transition metal, wherein the two adjoining S/D structures of the same partially metallized layer each comprise conductive material including oxygen and the Group V-VI transition metal. In an embodiment, a first stoichiometry of the transition metal oxide comprises a first mole ratio of oxygen to the Group V-VI transition metal. By contrast, a second stoichiometry of the conductive material comprises a second mole ratio of oxygen to the Group V-VI transition metal, wherein the second mole ratio is less than the first mole ratio. A gate of transistor structure 540, and the S/D structures of transistor structure 540, are variously coupled (directly or indirectly) each to a respective one of interconnect metallization features 516—e.g., to facilitate operation of transistor structure 540 and/or signal communication with any of various other suitable circuit components which IC device 500 includes, or is to be coupled to.

In an embodiment, the FEOL circuit structures include one or more levels of interconnect metallization features 516 electrically insulated by dielectric materials 512 and 514. In the exemplary embodiment illustrated, the FEOL circuit structures include metal-one (M1), metal-two (M2), and metal-three (M3) interconnect metallization levels. Interconnect metallization features 516 are of any metal(s) suitable for FEOL and/or BEOL IC interconnection. Dielectric material 514 may have a different composition that dielectric material 512, and may be of a composition that has a higher dielectric constant than that of dielectric material 512. In some examples wherein dielectric material 512 is predominantly silicon and oxygen (i.e., SiOₓ), dielectric material 514 is predominantly silicon and nitrogen (i.e., SiNₓ). In other examples, where dielectric material 512 is a low-k dielectric (e.g., carbon-doped silicon oxide, SiOC:H), dielectric material 514 is predominantly a higher-k dielectric (e.g., SiO₂).

In an illustrative scenario according to one embodiment, the FEOL circuit structures further comprise one or more transistors (such as the illustrative transistor structure 550 shown) which includes stacked channel structures. Because transistor structure 550 is over the other FEOL circuit structures, it is an upper-level transistor, while transistor structure 540, and transistors 530, are lower-level transistors. By way of illustration and not limitation, transistor structure 550 comprises multiple layers which are arranged in a vertical (z-axis) stack configuration. The multiple layers comprise a plurality of TMD layers which are each to provide a different respective channel structure, such as a nanoribbon. The multiple layers further comprise a plurality of partially metallized layers which are each formed on (and, for example, which each adjoin) a different respective one of the TMD layers. In one such embodiment, the plurality of partially metallized layers each comprise a respective two S/D structures, which each comprise a conductive material, and a respective gate dielectric structure which is between (and for example, which adjoins each of) the respective two S/D structures. For a given one of the plurality of partially metallized layers, the respective gate dielectric structure comprises an oxide of a Group V-VI transition metal, wherein the respective two S/D structures each comprise conductive material including oxygen and the Group V-VI transition metal. In an embodiment, a stoichiometry of the conductive material is substantially the same as that of a product of a plasma treatment of the oxide of the Group V-VI transition metal.

As further illustrated in FIG. 5, the BEOL circuit structures may further comprise any number of metallization levels, such as a metallization level (e.g., M5 and M6) above the metallization level (e.g., M4) at which transistor structure 550 resides. Any number of interconnect metallization levels may couple BEOL circuitry 560 to the underlying the FEOL circuit structures. In the example shown in FIG. 5, metallization levels of BEOL circuitry (e.g., M6) may be routed down through any number of metallization levels (e.g., M5-M3) to be in electrical communication with one or more FEOL transistors 530.

In further embodiments, there may be multiple levels of the BEOL circuit structures located over the FEOL circuit structures, with dielectric material between each BEOL device circuitry level. A level of the BEOL circuit structures may include a plurality of PMOS and/or NMOS transistor structures, for example. In other embodiments, an IC structure includes multiple levels of the BEOL circuit structures without any monocrystalline FEOL transistors. For such embodiments, one or more levels of transistor structures may be over any of various suitable substrates (e.g., polymer, glass, etc.).

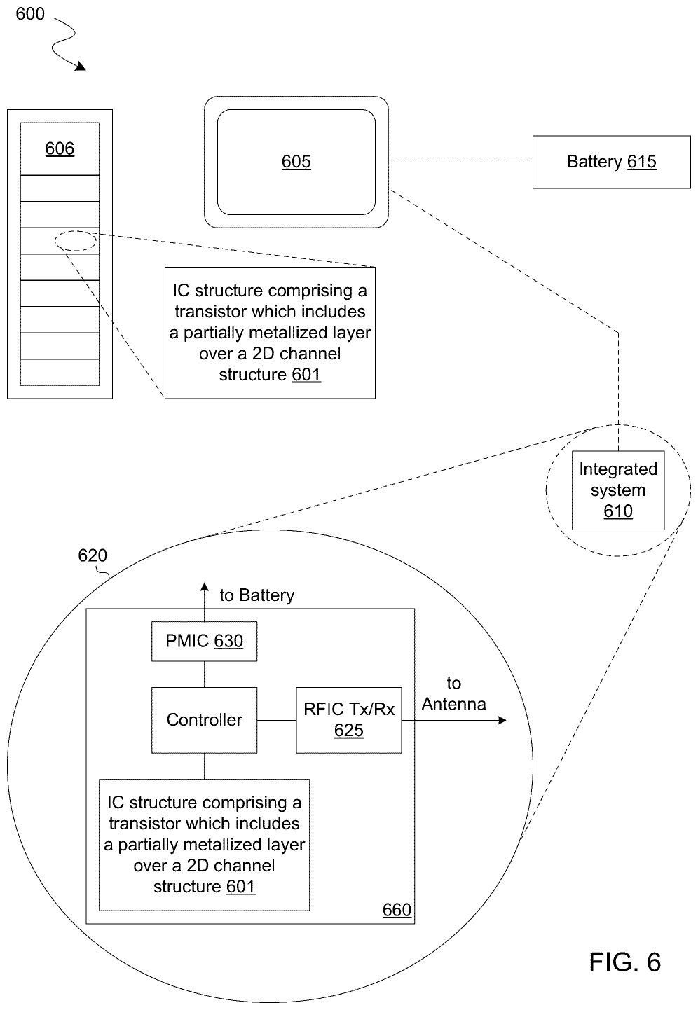

FIG. 6 illustrates a system 600 comprising a mobile computing platform 605 and a data server machine 606 employing a packaged IC die which include one or more metal chalcogenide transistors having respective partially metallized layer structures, for example as described elsewhere herein. Server machine 606 may be any commercial server, for example including any number of high-performance computing platforms disposed within a rack and networked together for electronic data processing, which in the exemplary embodiment includes a packaged IC die comprising IC structure 601, for example as described elsewhere herein.

The mobile computing platform 605 may be any portable device configured for each of electronic data display, electronic data processing, wireless electronic data transmission, or the like. For example, the mobile computing platform 605 may be any of a tablet, a smart phone, laptop computer, etc., and may include a display screen (e.g., a capacitive, inductive, resistive, or optical touchscreen), an integrated system 610, and a battery 615.

As illustrated in the expanded view 620, another IC structure 601 is additionally or alternatively coupled to host component 660. One or more of a power management integrated circuit (PMIC) 630 or RF (wireless) integrated circuit (RFIC) 625 including a wideband RF (wireless) transmitter and/or receiver may be further coupled to host component 660. PMIC 630 may perform battery power regulation, DC-to-DC conversion, etc., and so has an input coupled to battery 615 and with an output providing a current supply to other functional modules. As further illustrated, in the exemplary embodiment, RFIC 625 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

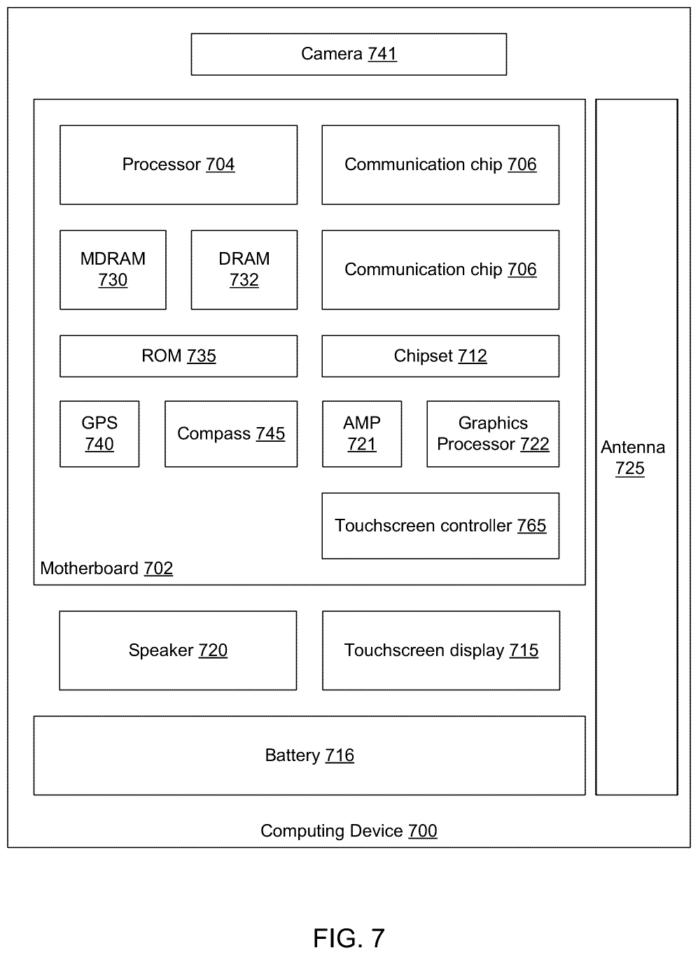

FIG. 7 is a functional block diagram of an electronic computing device 700, in accordance with some embodiments. Device 700 further includes a motherboard 702 hosting a number of components, such as, but not limited to, a processor 704 (e.g., an applications processor). Processor 704 may be physically and/or electrically coupled to motherboard 702. In some examples, processor 704 is part of a monolithic 3DIC structure, for example as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 706 may also be physically and/or electrically coupled to the motherboard 702. In further implementations, communication chips 706 may be part of processor 704. Depending on its applications, computing device 700 may include other components that may or may not be physically and electrically coupled to motherboard 702. These other components include, but are not limited to, volatile memory (e.g., DRAM 732), non-volatile memory (e.g., ROM 735), flash memory (e.g., NAND or NOR), magnetic memory (MRAM) 730, a graphics processor 722, a digital signal processor, a crypto processor, a chipset 712, an antenna 725, touchscreen display 715, touchscreen controller 765, battery 716, audio codec, video codec, power amplifier (AMP) 721, global positioning system (GPS) device 740, compass 745, accelerometer, gyroscope, speaker 720, camera 741, and mass storage device (such as hard disk drive, solid-state drive (SSD), compact disk (CD), digital versatile disk (DVD), and so forth, or the like.

Communication chips 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 706 may implement any of a number of wireless standards or protocols, including, but not limited to, those described elsewhere herein. As discussed, computing device 700 may include a plurality of communication chips 706. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

The description herein sets forth numerous details to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

In one or more first embodiments, a transistor structure comprises a first channel structure comprising a first transition metal dichalcogenide (TMD) material, a first layer comprising a first gate dielectric structure comprising a first body of a first dielectric material, wherein a first stoichiometry of the first dielectric material comprises oxygen and a first transition metal, wherein the first stoichiometry comprises a first mole ratio of oxygen to the first transition metal, and a first source or drain (S/D) electrode structure comprising a second body of a first conductive material, wherein the second body is adjacent to the first body, wherein a second stoichiometry of the first conductive material comprises oxygen and the first transition metal, wherein the second stoichiometry comprises a second mole ratio of oxygen to the first transition metal, and wherein the second mole ratio is less than the first mole ratio. The transistor structure further comprises a gate electrode structure which extends horizontally over the first body, and a first S/D contact structure which adjoins the second body.

In one or more second embodiments, further to the first embodiment, the first stoichiometry is substantially the same as that of a first oxide of a first transition metal, and the second stoichiometry is substantially the same as that of a product of a reaction between a plasma and the oxide of the first transition metal.

In one or more third embodiments, further to the second embodiment, the plasma is a hydrogen plasma or a nitrogen plasma.

In one or more fourth embodiments, further to the first embodiment or the second embodiment, the first channel structure is a monolayer structure.

In one or more fifth embodiments, further to the first embodiment or the second embodiment, the first transition metal is a Group V-VI transition metal.

In one or more sixth embodiments, further to the fifth embodiment, the Group V-VI transition metal is one of niobium (Nb), tantalum (Ta), vanadium (V), or molybdenum (Mo).

In one or more seventh embodiments, further to the first embodiment or the second embodiment, the first layer further comprises a second S/D electrode structure comprising a third body of the first conductive material, the third body is adjacent to the first body, and the transistor structure further comprises a second S/D contact structure which adjoins the third body.

In one or more eighth embodiments, further to the first embodiment or the second embodiment, the transistor structure further comprises a second gate dielectric structure between the first gate dielectric structure and the gate electrode structure.

In one or more ninth embodiments, further to the first embodiment or the second embodiment, the transistor structure further comprises a second channel structure comprising a second TMD material, wherein the second channel structure is arranged in a vertically stacked configuration with the first channel structure, and a second layer comprising a second gate dielectric structure comprising a third body of a second dielectric material, wherein a third stoichiometry of the second dielectric material comprises oxygen and a second transition metal, wherein the third stoichiometry comprises a third mole ratio of oxygen to the second transition metal, and a second S/D electrode structure comprising a fourth body of a second conductive material, wherein the fourth body is adjacent to the third body, wherein a fourth stoichiometry of the second conductive material comprises oxygen and the second transition metal, wherein the fourth stoichiometry comprises a fourth mole ratio of oxygen to the second transition metal, and wherein the third mole ratio is less than the fourth mole ratio.

In one or more tenth embodiments, further to the ninth embodiment, the third stoichiometry is substantially the same as that of a second oxide of the second transition metal, and the fourth stoichiometry of the second conductive material is substantially the same as that of a product of a reaction between the plasma and the second oxide of the second transition metal.

In one or more eleventh embodiments, further to the ninth embodiment, the gate electrode structure further extends horizontally over the third body, and the first S/D contact structure adjoins the fourth body.

In one or more twelfth embodiments, an integrated circuit (IC) die comprises a substrate structure comprising silicon, an insulator layer on the substrate structure, and a transistor on the insulator layer, the transistor comprising a first two-dimensional (2D) transition metal dichalcogenide (TMD) layer, a first body of a first dielectric material, wherein a first stoichiometry of the first dielectric material is substantially the same as that of a first oxide of a Group V-VI transition metal, wherein the first stoichiometry comprises a first mole ratio of oxygen to the Group V-VI transition metal, and a second body and a third body each of a first conductive material, wherein a second stoichiometry of the first conductive material comprises oxygen and the Group V-VI transition metal, wherein the second stoichiometry comprises a second mole ratio of oxygen to the Group V-VI transition metal, and wherein the second mole ratio is less than the first mole ratio, wherein the first 2D TMD layer adjoins each of the first body, the second body, and the third body, wherein the first body is between, and adjoins each of, the second body and the third body, and wherein the first body, the second body, and the third body each have a same first thickness along the first 2D TMD layer.

In one or more thirteenth embodiments, further to the twelfth embodiment, the Group V-VI transition metal is one of niobium (Nb), tantalum (Ta), vanadium (V), or molybdenum (Mo).

In one or more fourteenth embodiments, further to the twelfth embodiment or the thirteenth embodiment, the second stoichiometry is substantially the same as that of a product of a reaction between a plasma and the first oxide of the first transition metal.

In one or more fifteenth embodiments, further to the fourteenth embodiment, the plasma is a hydrogen plasma or a nitrogen plasma.

In one or more sixteenth embodiments, further to the twelfth embodiment or the thirteenth embodiment, the transistor further comprises a gate electrode structure which which extends horizontally over the first body, and a gate dielectric structure between the gate electrode structure and the first body.

In one or more seventeenth embodiments, further to the twelfth embodiment or the thirteenth embodiment, the transistor further comprises a second 2D TMD layer, a fourth body of the first dielectric material, and a fifth body and a sixth body each of the first conductive material, wherein the second 2D TMD layer adjoins each of the fourth body, the fifth body, and the sixth body, wherein the fourth body is between, and adjoins each of, the fifth body and the sixth body, and wherein the fourth body, the fifth body, and the sixth body each have a same second thickness along the second 2D TMD layer.

In one or more eighteenth embodiments, further to the twelfth embodiment or the thirteenth embodiment, the transistor further comprises a gate electrode structure which which extends horizontally over the first body, and a gate dielectric structure between the gate electrode structure and the first body.

In one or more nineteenth embodiments, further to the eighteenth embodiment, the gate electrode structure further extends horizontally over the third body, and the first S/D contact structure adjoins the fourth body.

In one or more twentieth embodiments, a method comprises receiving workpiece, forming a first layer of a first dielectric material on the workpiece, forming a second layer of a transition metal dichalcogenide (TMD) material on the first layer, forming a third layer of a second dielectric material on the second layer, wherein the second dielectric material comprises an oxide of a transition metal, forming a patterned structure on a first portion of the third layer, wherein a second portion of the third layer remains exposed by the patterned structure, performing a plasma treatment of the second portion of the third layer, wherein the plasma treatment forms a conductive body from the second portion, and forming a source or drain (S/D) contact over the conductive body.

In one or more twenty-first embodiments, further to the twentieth embodiment, the second layer is a monolayer structure.

In one or more twenty-second embodiments, further to the twentieth embodiment or the twenty-first embodiment, the first portion is to provide a gate dielectric structure, and forming the patterned structure comprises forming a gate electrode structure on the gate dielectric structure.

In one or more twenty-third embodiments, further to the twentieth embodiment or the twenty-first embodiment, the first portion is to provide a first gate dielectric structure, and forming the patterned structure comprises forming a second gate dielectric structure on the first gate dielectric structure.

In one or more twenty-fourth embodiments, further to the twentieth embodiment or the twenty-first embodiment, the transition metal is a Group V-VI transition metal.

In one or more twenty-fifth embodiments, further to the twenty-fourth embodiment, the Group V-VI transition metal is one of niobium (Nb), tantalum (Ta), vanadium (V), or molybdenum (Mo).

In one or more twenty-sixth embodiments, further to the twentieth embodiment or the twenty-first embodiment, the plasma treatment further forms another conductive body from a third portion of the third layer, wherein the first portion is between the second portion and the third portion, and wherein the third portion remains exposed by the patterned structure.

In one or more twenty-seventh embodiments, further to the twenty-sixth embodiment, the method further comprises forming another S/D contact over the other conductive body.

In one or more twenty-eighth embodiments, further to the twentieth embodiment or the twenty-first embodiment, the method further comprises forming a fourth layer of a third dielectric material over the first portion, forming a fifth layer of the TMD material on the fourth layer, forming a sixth layer of a fourth dielectric material on the fifth layer, wherein the fourth dielectric material comprises a second oxide of the transition metal, forming a second patterned structure on a third portion of the sixth layer, wherein a fourth portion of the sixth layer remains exposed by the second patterned structure, wherein the plasma treatment further forms another conductive body from the fourth portion of the sixth layer, and forming another S/D contact over the other conductive body.

In one or more twentieth embodiments, further to the twentieth embodiment or the twenty-first embodiment, performing the plasma treatment comprises reacting the second portion with a hydrogen plasma or a nitrogen plasma.

Techniques and architectures for providing transistor structures are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A transistor structure comprising:
a first channel structure comprising a first transition metal dichalcogenide (TMD) material;
a first layer comprising:
a first gate dielectric structure comprising a first body of a first dielectric material, wherein a first stoichiometry of the first dielectric material comprises oxygen and a first transition metal, wherein the first stoichiometry comprises a first mole ratio of oxygen to the first transition metal; and
a first source or drain (S/D) electrode structure comprising a second body of a first conductive material, wherein the second body is adjacent to the first body, wherein a second stoichiometry of the first conductive material comprises oxygen and the first transition metal, wherein the second stoichiometry comprises a second mole ratio of oxygen to the first transition metal, and wherein the second mole ratio is less than the first mole ratio;
a gate electrode structure which extends horizontally over the first body; and
a first S/D contact structure which adjoins the second body.

2. The transistor structure of claim 1, wherein:
the first stoichiometry is substantially the same as that of a first oxide of a first transition metal; and
the second stoichiometry is substantially the same as that of a product of a reaction between a plasma and the oxide of the first transition metal.

3. The transistor structure of claim 1, wherein the first channel structure is a monolayer structure.

4. The transistor structure of claim 1, wherein the first transition metal is a Group V-VI transition metal.

5. The transistor structure of claim 4, wherein the Group V-VI transition metal is one of niobium (Nb), tantalum (Ta), vanadium (V), or molybdenum (Mo).

6. The transistor structure of claim 1, wherein:
the first layer further comprises a second S/D electrode structure comprising a third body of the first conductive material;
the third body is adjacent to the first body; and
the transistor structure further comprises a second S/D contact structure which adjoins the third body.

7. The transistor structure of claim 1, further comprising a second gate dielectric structure between the first gate dielectric structure and the gate electrode structure.

8. The transistor structure of claim 1, further comprising:
a second channel structure comprising a second TMD material, wherein the second channel structure is arranged in a vertically stacked configuration with the first channel structure; and
a second layer comprising:
a second gate dielectric structure comprising a third body of a second dielectric material, wherein a third stoichiometry of the second dielectric material comprises oxygen and a second transition metal, wherein the third stoichiometry comprises a third mole ratio of oxygen to the second transition metal; and
a second S/D electrode structure comprising a fourth body of a second conductive material, wherein the fourth body is adjacent to the third body, wherein a fourth stoichiometry of the second conductive material comprises oxygen and the second transition metal, wherein the fourth stoichiometry comprises a fourth mole ratio of oxygen to the second transition metal, and wherein the third mole ratio is less than the fourth mole ratio.

9. The transistor structure of claim 8, wherein:
the third stoichiometry is substantially the same as that of a second oxide of the second transition metal; and
the fourth stoichiometry of the second conductive material is substantially the same as that of a product of a reaction between the plasma and the second oxide of the second transition metal.

10. The transistor structure of claim 8, wherein:
the gate electrode structure further extends horizontally over the third body; and
the first S/D contact structure adjoins the fourth body.

11. An integrated circuit (IC) die comprising:
a substrate structure comprising silicon;
an insulator layer on the substrate structure; and
a transistor on the insulator layer, the transistor comprising:
a first two-dimensional (2D) transition metal dichalcogenide (TMD) layer;
a first body of a first dielectric material, wherein a first stoichiometry of the first dielectric material is substantially the same as that of a first oxide of a Group V-VI transition metal, wherein the first stoichiometry comprises a first mole ratio of oxygen to the Group V-VI transition metal; and
a second body and a third body each of a first conductive material, wherein a second stoichiometry of the first conductive material comprises oxygen and the Group V-VI transition metal, wherein the second stoichiometry comprises a second mole ratio of oxygen to the Group V-VI transition metal, and wherein the second mole ratio is less than the first mole ratio;
wherein the first 2D TMD layer adjoins each of the first body, the second body, and the third body, wherein the first body is between, and adjoins each of, the second body and the third body, and wherein the first body, the second body, and the third body each have a same first thickness along the first 2D TMD layer.

12. The IC die of claim 11, wherein the second stoichiometry is substantially the same as that of a product of a reaction between a plasma and the first oxide of the first transition metal.

13. The IC die of claim 11, wherein the transistor further comprises:
a gate electrode structure which extends horizontally over the first body; and
a gate dielectric structure between the gate electrode structure and the first body.

14. The IC die of claim 11, wherein the transistor further comprises:
a second 2D TMD layer;
a fourth body of the first dielectric material; and
a fifth body and a sixth body each of the first conductive material;
wherein the second 2D TMD layer adjoins each of the fourth body, the fifth body, and the sixth body, wherein the fourth body is between, and adjoins each of, the fifth body and the sixth body, and wherein the fourth body, the fifth body, and the sixth body each have a same second thickness along the second 2D TMD layer.

15. A method comprising:
receiving workpiece;
forming a first layer of a first dielectric material on the workpiece;
forming a second layer of a transition metal dichalcogenide (TMD) material on the first layer;
forming a third layer of a second dielectric material on the second layer, wherein the second dielectric material comprises an oxide of a transition metal;
forming a patterned structure on a first portion of the third layer, wherein a second portion of the third layer remains exposed by the patterned structure;
performing a plasma treatment of the second portion of the third layer, wherein the plasma treatment forms a conductive body from the second portion; and
forming a source or drain (S/D) contact over the conductive body.

16. The method of claim 15, wherein the second layer is a monolayer structure.

17. The method of claim 15, wherein:
the first portion is to provide a gate dielectric structure; and
forming the patterned structure comprises forming a gate electrode structure on the gate dielectric structure.

18. The method of claim 15, wherein:
the first portion is to provide a first gate dielectric structure; and
forming the patterned structure comprises forming a second gate dielectric structure on the first gate dielectric structure.

19. The method of claim 15, wherein the transition metal is a Group V-VI transition metal.

20. The method of claim 15, further comprising:
forming a fourth layer of a third dielectric material over the first portion;
forming a fifth layer of the TMD material on the fourth layer;
forming a sixth layer of a fourth dielectric material on the fifth layer, wherein the fourth dielectric material comprises a second oxide of the transition metal;
forming a second patterned structure on a third portion of the sixth layer, wherein a fourth portion of the sixth layer remains exposed by the second patterned structure, wherein the plasma treatment further forms another conductive body from the fourth portion of the sixth layer; and
forming another S/D contact over the other conductive body.
